(19) United States
(12) Patent Application Publication
(10) Pub. No.: US 2026/0363081 A1
(43) Pub. Date: Nov. 12, 2026

(54) ULTRA-HIGH TENSILE WAFER BOW MANAGEMENT

(71) Applicant: Applied Materials, Inc., Santa Clara, CA (US)

(72) Inventors: ZHEN XU, Cupertino, CA (US); KWANGDUK LEE, Redwood City, CA (US); SEUNGGYU KIM, Osan-Si (KR); JUNJUNG KIM, Georgetown, TX (US); MASSIMILIANO RIGHI, Lombardia (IT); SANG-JIN KIM, San Jose, CA (US)

(21) Appl. No.: 19/200,514

(22) Filed: May 6, 2025

(51) Int. Cl. H10W 42/00; H10P 14/60; H10P 14/692; H10P 14/694; H10P 74/00

(52) U.S. Cl. CPC H10W 42/121; H10P 14/6336; H10P 14/69215; H10P 14/69433; H10P 74/23

(57) ABSTRACT

Embodiments described herein relate to a method that includes depositing a first layer with a first material composition on a surface of a substrate, where the substrate has a first bow prior to depositing the first layer on the surface of the substrate. In an embodiment, the first layer includes a tensile stress with a first magnitude. In an embodiment, the method further includes depositing a second layer with a second material composition on the first layer, where the second layer includes a compressive stress with a second magnitude. In an embodiment, the second magnitude is smaller than the first magnitude, and the first layer and the second layer produce a second bow for the substrate that is different than the first bow.

### BACKGROUND

### 1) Field

Embodiments relate to the field of semiconductor manufacturing and, in particular, processes for depositing bow reduction stacks that comprise alternating high tensile stress layers and compressive capping layers.

### 2) Description of Related Art

Some semiconductor based products rely on the stacking of multiple thin films. Memory devices (e.g., 3D NAND) are one such device. For example, the memory device may include many alternating insulating layers and conductive layers. The stress from the thin films results in warpage or bowing of the underlying substrate (e.g., a semiconductor wafer). As the number of layers increase, the resulting bow in the substrate becomes problematic. In some instances, the bow can become so large that subsequent manufacturing becomes difficult or impossible. For example, the bow may result in the substrate not being able to be chucked to an electrostatic chuck for processing, or the bow may result in significant processing nonuniformity.

Accordingly, attempts to improve warpage and/or bowing have been proposed. One solution is to provide backside layers on the substrate that induce an opposing stress on the substrate. Ideally, the opposing stress will substantially cancel the stress applied by the device side layers. However, as stresses continue to increase due to the inclusion of more layers, the backside layer is not able to fully counteract the stress. This is because the backside layer cannot be continually increased in thickness due to cracking and/or delamination.

### SUMMARY

Embodiments described herein relate to a method that includes depositing a first layer with a first material composition on a surface of a substrate, where the substrate has a first bow prior to depositing the first layer on the surface of the substrate. In an embodiment, the first layer includes a tensile stress with a first magnitude. In an embodiment, the method further includes depositing a second layer with a second material composition on the first layer, where the second layer includes a compressive stress with a second magnitude. In an embodiment, the second magnitude is smaller than the first magnitude, and the first layer and the second layer produce a second bow for the substrate that is different than the first bow.

Embodiments described herein relate to a method that includes depositing a first bow modification stack on a surface of a substrate. In an embodiment, the first bow modification stack includes a first layer including a first tensile stress, and a second layer including a first compressive stress, where the first bow modification stack has a first net tensile stress. In an embodiment, the method further includes depositing a second bow modification stack on the first bow modification stack. In an embodiment, the second bow modification stack includes a third layer including a second tensile stress, and a fourth layer including a second compressive stress. In an embodiment, the second bow modification stack has a second net tensile stress.

Embodiments described herein relate to a method that includes calculating a magnitude of tensile stress to apply to a substrate in order to change an amount of bow in the substrate to at least a desired threshold. In an embodiment, the method further includes applying a bow modification stack to the substrate, where the bow modification stack includes alternating tensile layers and compressive layers. In an embodiment, a sum of the stress provided by the alternating tensile layers and compressive layers is at least equal to the magnitude of tensile stress to apply to the substrate.

### BRIEF DESCRIPTION OF THE DRAWINGS

FIG. 1A is a cross-sectional illustration of a substrate that has a bow, in accordance with an embodiment.

FIG. 1B is a cross-sectional illustration of a substrate that has a bow and a backside bow reduction layer that is cracked, in accordance with an embodiment.

FIG. 2 is a cross-sectional illustration of a substrate that has a backside bow modification stack that comprises a tensile layer and a compressive layer, in accordance with an embodiment.

FIG. 3 is a graph that shows the impact of wafer bow with respect to a number of deposition cycles in a backside bow modification stack, in accordance with an embodiment.

FIG. 4A is a cross-sectional illustration of a substrate that comprises a backside bow modification stack with a plurality of alternating tensile layers and compressive layers, in accordance with an embodiment.

FIG. 4B is a cross-sectional illustration of a substrate that comprises a backside bow modification stack with a plurality of alternating tensile layers and compressive layers with a thicker capping layer, in accordance with an embodiment.

FIG. 4C is a cross-sectional illustration of a substrate that comprises a backside bow modification stack with a plurality of alternating tensile layers and compressive layers, where the compressive layers have a non-uniform thickness, in accordance with an embodiment.

FIG. 4D is a cross-sectional illustration of a substrate that comprises a backside bow modification stack with a plurality of alternating compressive layers and tensile layers, where the tensile layers have a non-uniform thickness, in accordance with an embodiment.

FIG. 5 is a plan view schematic illustration of a processing tool that may be used to deposit a backside bow modification stack with a plurality of alternating compressive layers and tensile layers on a substrate for bow modification purposes, in accordance with an embodiment.

FIG. 6 is a flow diagram that depicts a process for forming a backside bow modification stack on a substrate, where the bow modification stack comprises alternating tensile layers and compressive layers, in accordance with an embodiment.

FIG. 7 is a flow diagram that depicts a process for forming a backside bow modification stack on a substrate to reduce the bow of a substrate to a desired threshold, in accordance with an embodiment.

FIG. 8 illustrates a block diagram of an exemplary computer system that may be used in conjunction with a processing tool, in accordance with an embodiment.

### DETAILED DESCRIPTION

Embodiments described herein include apparatuses and methods for depositing bow reduction stacks that comprise alternating high tensile stress layers and compressive capping layers, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, the presence of wafer bow can result in manufacturing difficulties. For example, extreme wafer bow may make it difficult (or impossible) to chuck the wafer with an electrostatic chuck. Additionally, wafer bow may make process uniformity across the wafer more difficult. That is, deposition thicknesses of a given layer may not be uniform across the surface of the wafer. For this reason, attempts have been made to provide wafer bow and/or warpage mitigation. One solution for providing wafer bow and/or warpage mitigation is through the use of a backside bow reduction layer.

The backside bow reduction layer is typically engineered to induce a stress into the substrate that is opposite from the stress applied by device layers formed on the opposing surface of the substrate. However, the stress applied by the device layers continues to increase as the layer count grows. This is problematic since the backside bow reduction layer cannot continue to grow in thickness to negate the additional magnitude of the induced stress. It has been shown that as the thickness of the backside bow reduction layer increases beyond a certain thickness, the backside bow reduction layer begins to crack and/or delaminate from the substrate. As such, the desired amount of compensating stress from the backside bow reduction layer cannot be induced into the substrate to negate the stress applied by the device layers on the opposing surface.

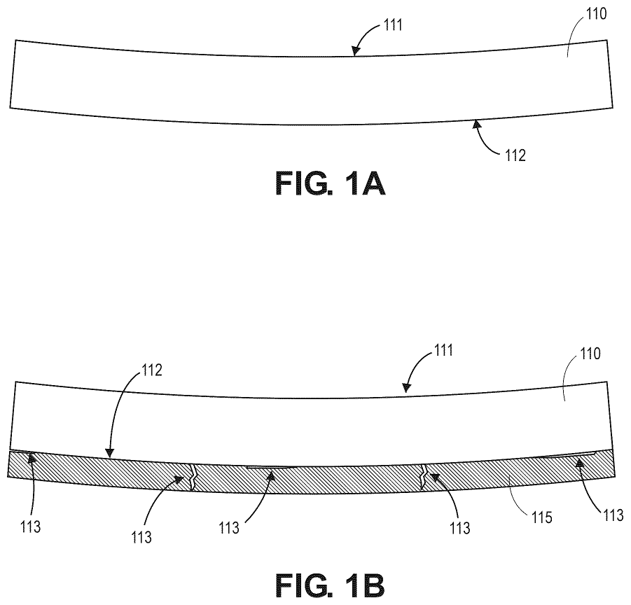

An example of such an issue is shown in FIGS. 1A and 1B. FIG. 1A is a cross-sectional illustration of a substrate 110. The substrate 110 may comprise a semiconductor substrate, such as a silicon wafer or any other type of wafer. The substrate 110 may have a first surface 111 and a second surface 112. As shown, the surfaces 111 and 112 are bowed. The bow of the substrate 110 may be the result of one or more device layers (not shown in FIG. 1A) that are formed over the first surface 111. In the illustrated embodiment, the bow of the substrate 110 is shown as a dished bow (e.g., with a tensile stress applied to the first surface 111 by the device layers). However, the bow of the substrate 110 may also be in the opposite direction (e.g., with a compressive stress applied to the first surface 111 by the device layers).

FIG. 1B is a cross-sectional illustration of the substrate 110 after an attempt to correct the bow is made. As shown, a backside bow reduction layer 115 may be deposited over the second surface 112. The bow reduction layer 115 may comprise a stress that is opposite from the stress applied by the device layers in order to counteract the bow in the substrate 110. However, when the thickness of the bow reduction layer 115 increases past a desired level, the bow reduction layer 115 may develop cracks 113 and/or delaminate from the substrate 110. For example, it has been shown that a thickness of the bow reduction layer 115 of approximately 1.0 μm or higher will result in cracking when applied to a semiconductor wafer. In the case of an amorphous silicon bow reduction layer 115, a thickness up to approximately 1.0 μm may allow for bow reduction up to approximately 580 μm. However, substrate bow may extend significantly beyond 580 μm (e.g., up to approximately 1,000 μm or more). As such, alternative bow reduction processes and structures are needed to enable the manufacture of such devices.

Embodiments disclosed herein may include a bow reduction stack that enables an increase in the bow compensation that can be applied to the backside of the substrate. Instead of a single layer that is grown to provide a desired bow compensation, a stack of alternating tensile layers and compressive layers may be used to increase the total bow compensation without cracking or delamination. When bow compensation is implemented through only a tensile film, a thick tensile film will tend to start cracking at the top due to larger deformation. Adjoined compressive stress from the interlayer may partially counter this effect. This leads to the ability to provide a larger overall bow compensation before the tensile stress of the film reaches a critical point that causes cracking.

It is to be appreciated that the total bow applied to the substrate may substantially equal the magnitude of the total bow applied by the plurality of tensile layers subtracted by the magnitude of the total bow applied by the plurality of compressive layers. As such, the magnitude of the total bow applied by the plurality of tensile layers will be much greater than the magnitude of the total stress applied by the plurality of compressive layers. For example, the compressive layers may be thinner than the tensile layers. However, if a bow in the opposite direction needs to be corrected, a new combination of high compressive and low tensile films may be selected.

In an embodiment, the tensile layers may comprise an amorphous silicon material. In order to increase the magnitude of the tensile stress for a given thickness of the amorphous silicon layer, one or more dopants may be added to the compressive layer. For example, the dopants may include boron, nitrogen, or the like. In an embodiment, any other suitable tensile film layer may be used. For example, a high tensile silicon nitride film may be used as the tensile layer in some embodiments.

In an embodiment, the compressive layer may comprise an oxide material (e.g., silicon oxide) or the like. Compressive nitride materials may also be used in some embodiments. In an embodiment, the compressive layer may also function as a protective capping layer. For example, it has been shown that moisture absorption by the tensile layer may result in a reduction of the tensile stress, cracking, and/or delamination. Accordingly, the outermost compressive layer may have a greater thickness in order to further mitigate moisture absorption by the underlying tensile layers.

In an embodiment, the tensile layers and the compressive layers may be formed in a single deposition processing chamber. For example, a plasma enhanced chemical vapor deposition (PECVD) chamber may be used to form the alternating tensile layers and compressive layers. As such, a single chamber within a larger cluster tool may be used to implement the bow reduction stack.

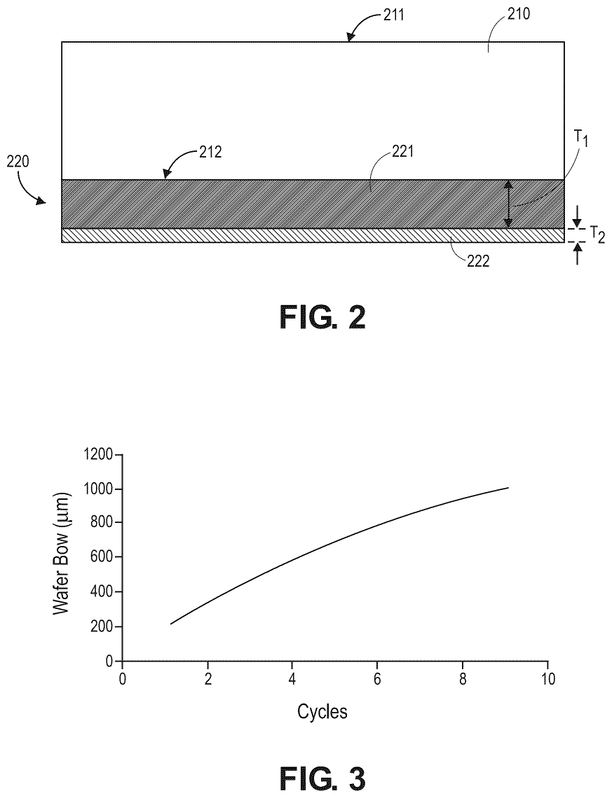

Referring now to FIG. 2, a cross-sectional illustration of a portion of a substrate 210 is shown, in accordance with an embodiment. In an embodiment, the substrate 210 may comprise a semiconductor substrate. The semiconductor substrate may be a silicon wafer, a III-V semiconductor wafer, or the like. The substrate 210 may have any suitable form factor. For example, the form factor may include a 200 mm wafer, a 300 mm wafer, a 400 mm wafer, or the like. In an embodiment, the substrate 210 has a first surface 211 and a second surface 212. The first surface 211 may be the surface on which devices are formed. For example, one or more device layers (not shown) may be formed on the first surface. In some embodiments, one or more of the device layers are formed prior to the formation of the bow reduction stack 220 on the second surface 212. In other embodiments, one or more of the device layers are formed after the formation of the bow reduction stack 220 on the second surface 212.

In an embodiment, the bow reduction stack 220 may comprise a first layer 221 and a second layer 222. The first layer 221 and the second layer 222 may have opposite stress directions. For example, the first layer 221 may be a tensile stress layer and the second layer 222 may be a compressive stress layer. The magnitude of the stress in the first layer 221 and the magnitude of the stress in the second layer 222 are different from each other so that a total stress of the bow reduction stack 220 is non-zero. Depending on the desired direction of bow correction for the substrate 210, the total stress of the bow reduction stack 220 may be tensile or compressive. However, through the remainder of the description herein, the first layer 221 will be considered tensile and the second layer 222 will be considered compressive, and the total stress of the bow reduction stack 220 will be considered as being tensile. Though, since films described herein are deposited on the back of the substrate 210, the film will provide compressive bow compensation to the substrate 210.

In an embodiment, the net tensile stress applied by the bow reduction stack 220 may be provided by having a first layer 221 with a first thickness T₁ that is greater than a second thickness T₂ of the second layer 222. In some embodiments, the first thickness T₁ may be two or more times thicker than the second thickness T₂, or the first thickness T₁ may be four or more times thicker than the second thickness T₂. In an embodiment, the first thickness T₁ may be up to a thickness that leads to cracking and/or delamination of the first layer 221. For example, the first thickness T₁ may be up to approximately 0.6 μm or up to approximately 1.0 μm.

In an embodiment, the first layer 221 may comprise an amorphous silicon material. In order to increase the magnitude of the strain per unit thickness, the first layer 221 may also comprise dopants. For example, one or more of boron, nitrogen, and/or the like be added into the first layer as a dopant to increase the tensile stress of the first layer 221. While amorphous silicon is one suitable tensile material, any suitable film that has a tensile stress may be used, such as a tensile silicon nitride material or the like. In an embodiment, the second layer 222 may comprise any material that is compressive when applied as a thin film. In an embodiment, the second layer 222 may comprise an oxide, such as a silicon oxide. Though, other materials, such as a compressive nitride film, may also be used in some embodiments.

In the embodiment illustrated in FIG. 2, the second layer 222 is used as a capping layer that prevents damage (e.g., through moisture absorption or the like) to the underlying first layer 221. However, in additional embodiments described herein, multiple iterations of the first layer 221 and the second layer 222 may be used in the bow reduction stack 220. For example, a plurality of cycles (e.g., where each cycle comprises the deposition of a first layer 221 and a deposition of a second layer 222) may be used to increase the amount of bow reduction that can be applied to the substrate 210.

In such an embodiment, the second layers 222 also function as a “lock in” layer or a “reset” layer. That is, the subsequently deposited first layer 221 on the underlying second layer 222 is able to be deposited to a desired thickness before cracking or delaminating occurs. As such, the combined thickness of the multiple first layers 221 may be greater than the maximum thickness that is obtainable through the use of a single first layer 221 without any intervening layers. For example, whereas a single first layer 221 may be limited to a maximum thickness of approximately 1.0 μm before cracking, embodiments disclosed herein allow for a plurality of first layers 221 to be stacked (with intervening second layers 222) so that the total thickness of the plurality of first layers 221 is greater than 1.0 μm. As such, the magnitude of bow that can be applied to the substrate 210 can be significantly increased.

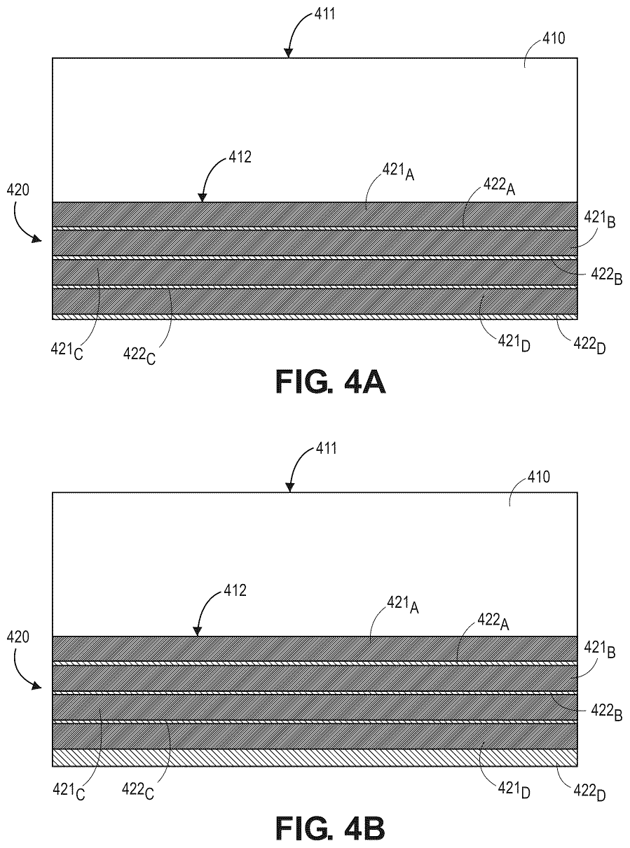

Referring now to FIG. 3 a graph that depicts the magnitude of bow correction for a given number of cycles is shown, in accordance with an embodiment. In FIG. 3 each cycle includes the deposition of a first layer and a second layer. For example, the first layer and the second layer may be similar to the first layer 221 and the second layer 222 described above with respect to FIG. 2. With each subsequent cycle, the first layer 221 may be deposited on the outermost second layer 222. In this way a multilayer stack may be formed to increase the magnitude of the bow correction.

As noted above, the use of a single stress inducing layer is limited to correcting about 580 μm of bow. However, as shown in FIG. 3, the bow correction may continue to approximately 1,000 μm or more. While nine cycles are shown in FIG. 3, it is to be appreciated that the number of cycles may continue since the cracking and delaminating behavior is mitigated due to the presence of the intervening second layers that function as a reset layer for each of the stress inducing first layers.

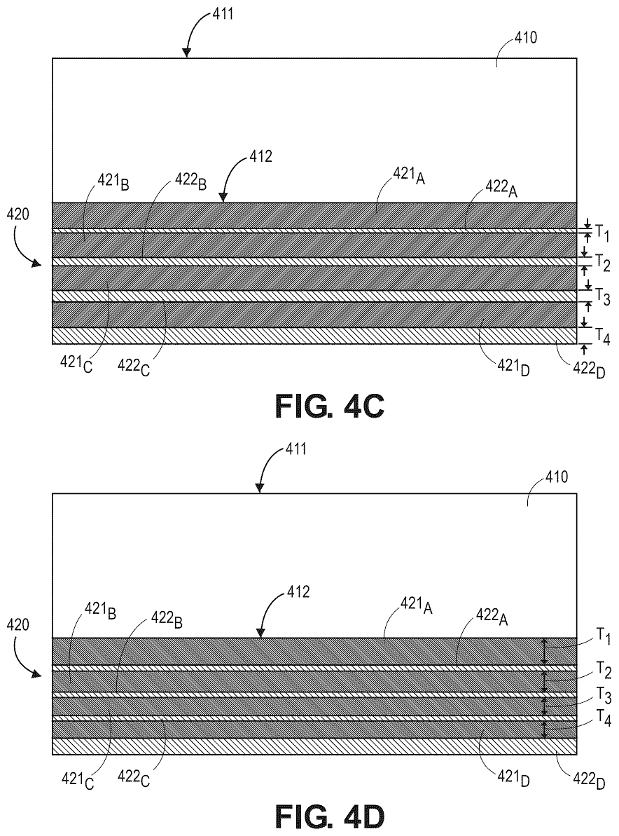

Referring now to FIG. 4A-4D, a series of cross-sectional illustrations depicting a series of substrates 410 with bow mitigation stacks 420 is shown, in accordance with various embodiments. Each of the substrates 410 may be similar to the substrate 210 described in greater detail above. The bow mitigation stacks 420 may comprise alternating first layers 421 and second layers 422. The first layers 421 may be similar to first layers 221 described above, and the second layers 422 may be similar to the second layers 222 described above. In a particular embodiment, the first layers 421 may induce tensile stress into the substrate 410 and the second layers 422 may be compressive layers. For example, the first layers 421 may comprise amorphous silicon with (or without) doping (e.g., boron, nitrogen, etc.), and the second layers 422 may comprise silicon oxide or the like.

In the illustrated embodiments of FIG. 4A-4D, four deposition cycles are provided for each of the bow mitigation stacks 420 so that there are four first layers 421_{A}-421_{D} and four second layers 422_{A}-422_{D}. Though, it is to be appreciated that the bow mitigation stacks 420 may comprise any number of first layers 421 and second layers 422.

Referring now to FIG. 4A, a cross-sectional illustration of a substrate 410 with a bow mitigation stack 420 is shown, in accordance with an embodiment. In an embodiment, the bow mitigation stack 420 is formed on a backside surface 412 of the substrate 410 that is opposite from a device surface 411 of the substrate 410. In an embodiment, one or more device layers (not shown in FIG. 4A) may be formed over the device surface 411.

In the illustrated embodiment, each deposition cycle of the bow mitigation stack 420 comprises a first layer 421 and a second layer 422. As shown, each of the first layers 421_{A}-421_{D} have a substantially uniform thickness. Similarly, each of the second layers 422_{A}-422_{D} have a substantially uniform thickness. In an embodiment, each of the first layers 421_{A}-421_{D} may have substantially uniform compositions as well. In other embodiments, the first layers 421_{A}-421_{D} may have different compositions. For example, a doping concentration may be nonuniform between the different first layers 421_{A}-421_{D}. Such an embodiment may allow for the formation of a stress gradient through a thickness of the bow mitigation stack 420. In an embodiment, each of the second layers 422_{A}-422_{D} may also have substantially uniform compositions. Other embodiments may include second layers 422_{A}-422_{D} that have different material compositions. For example, the material composition of the outermost second layer 422_{D} may be specifically tuned to provide moisture protection to the remainder of the bow modification stack 420.

Referring now to FIG. 4B, a cross-sectional illustration of a substrate 410 with a bow modification stack 420 is shown, in accordance with an additional embodiment. In an embodiment, the bow modification stack 420 in FIG. 4B may be similar to the bow modification stack 420 in FIG. 4A with the exception of the thickness uniformity of the second layers 422_{A}-422_{D}. Instead of all of the second layers 422_{A}-422_{D} having substantially similar thicknesses, one or more of the second layers 422_{A}-422_{D} may have a different thickness. Particularly, the outermost second layer 422_{D} may have a thickness that is greater than the thicknesses of any of the other second layers 422_{A}, 422_{B}, or 422_{C}. Such an embodiment may be beneficial in order to increase the environmental protection to the remainder of the underlying bow mitigation stack 420. For example, a thicker second layer 422_{D} may be used to prevent moisture absorption extensively by underlying first layers 421_{A}-421_{D}.

Referring now to FIG. 4C, a cross-sectional illustration of a substrate 410 and a bow mitigation stack 420 is shown, in accordance with an additional embodiment. The bow mitigation stack 420 in FIG. 4C may be similar to the bow mitigation stack 420 in FIG. 4B, with the exception of the thicknesses of the second layers 422_{A}-422_{D}. As shown in FIG. 4C, the second layers 422_{A} 422_{D} may all have different thicknesses. In the particular embodiment shown in FIG. 4C, the second layer 422_{A} has a first thickness T₁, the second layer 422_{B} has a second thickness T₂, the second layer 422_{C} has a third thickness T₃, and the second layer 422_{D} has a fourth thickness T₄. In an embodiment, the first thickness T₁ is the smallest, the second thickness T₂ is greater than the first thickness T₁, the third thickness T₃ is greater than the second thickness T₂, and the fourth thickness T₄ is greater than the third thickness. While second layers 422 with thicknesses that increase as the distance from the substrate increases is shown, it is to be appreciated that any pattern (or lack of pattern) with respect to the change in thickness of the second layers 422 may be used in different embodiments.

Referring now to FIG. 4D, a cross-sectional illustration of a substrate 410 and a bow mitigation stack 420 is shown, in accordance with an additional embodiment. The bow mitigation stack 420 in FIG. 4D may be similar to the bow mitigation stack 420 in FIG. 4B, with the exception of the thickness of the first layers 421_{A}-422_{D}. As shown, the first layer 421_{A} has a first thickness T₁, the first layer 421_{B} has a second thickness T₂, the first layer 421_{C} has a third thickness T₃, and the first layer 421_{D} has a fourth thickness T₄. In the illustrated embodiment, the thicknesses T₁-T₄ decrease with distance from the substrate 410. Decreasing the thickness of the first layer 421 with distance from the substrate 410 may be beneficial since more frequent compressive second layers 422 may be needed as the cracking threshold of the first layers 421 is approached. Though, it is to be appreciated that any pattern (or lack of pattern) with respect to the change in thickness of the first layers 421 may be used in different embodiments.

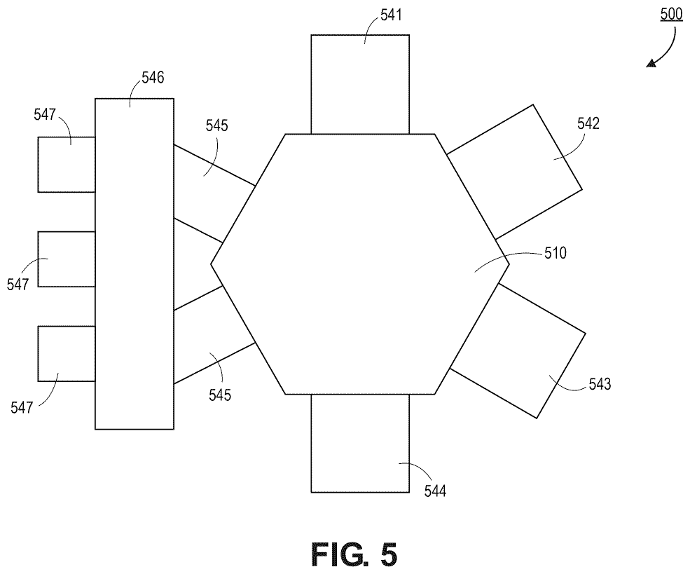

Referring now to FIG. 5, a plan view illustration of a processing tool 500 that is used to process substrates that include a bow mitigation stack is shown, in accordance with an embodiment. In an embodiment, the processing tool 500 may comprise a transfer chamber 540 that is coupled to a plurality of processing chambers 541-544. One or more of the processing chambers 541-544 may be suitable for depositing the bow mitigation stack on substrates, and one or more of the processing chambers 541-544 may be suitable for depositing one or more different device layers on the substrate opposite from the bow mitigation stack.

In a particular embodiment, processing chamber 541 may comprise a PECVD chamber that is used to deposit alternating tensile layers and compressive layers to form the bow mitigation stack on the substrate. In some embodiments, the chamber 542 may be a cooling station where the substrate may sit while cleaning and seasoning operations are implemented on processing chamber 541. Though, the substrates may be stored at any location within the tool 500. In an embodiment, the processing tool 500 may further comprise one or more load locks 545 to couple the vacuum environment of the transfer chamber 540 to a factory interface (FI) 546. The FI 546 may receive one or more substrate carriers 547, such as front opening unified pods (FOUPS) or the like.

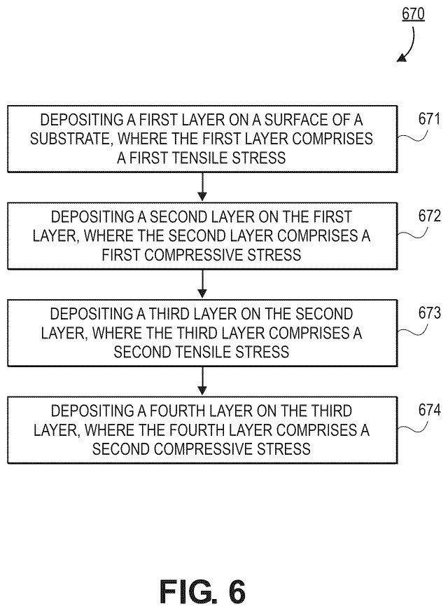

Referring now to FIG. 6, a flow diagram that depicts a process 670 for forming a bow mitigation stack on the backside of a substrate is shown, in accordance with an embodiment. In an embodiment, the bow mitigation stack may be similar to any of the bow mitigation stacks described in greater detail herein. In an embodiment, the process 670 may begin with operation 671, which comprises depositing a first layer on a surface of a substrate. In an embodiment, the first layer may comprise a first tensile stress. For example, the first layer may comprise amorphous silicon with (or without) dopants (e.g., boron, nitrogen, or the like). In an embodiment, the first layer may have a thickness up to approximately 1.0 μm.

In an embodiment, the process 670 may continue with operation 672, which comprises depositing a second layer on the first layer. In an embodiment, the second layer comprises a first compressive stress. In an embodiment, a magnitude of the first compressive stress is smaller than a magnitude of the first tensile stress. A thickness of the second layer may be smaller than the thickness of the first layer. The second layer may comprise any suitable film that provides a compressive stress. For example, the compressive second layer may comprise a silicon oxide film or the like.

In an embodiment, the process 670 may continue with operation 673, which comprises depositing a third layer on the second layer. In an embodiment, the third layer comprises a second tensile stress. In some embodiments, the third layer may be similar to the first layer. The third layer may have a thickness that is approximately 1.0 μm or less. The third layer may comprise amorphous silicon with (or without) dopants (e.g., boron, nitrogen, or the like).

In an embodiment the process 670 may continue with operation 674, which comprises depositing a fourth layer on the third layer. In an embodiment, the fourth layer may comprise a second compressive stress. In an embodiment, the fourth layer may be similar to the second layer. For example, the fourth layer may comprise a silicon oxide material or the like. A thickness of the fourth layer may be smaller than a thickness of the third layer.

In an embodiment, the process 670 may continue with any number of additional cycles of forming tensile layers and compressive layers. Each cycle may be substantially similar to each other. Though, deposition conditions, durations, and/or the like may be modified for each of the cycles in order to provide a bow mitigation stack that has layers of nonuniform thickness and/or nonuniform composition, similar to other embodiments described herein.

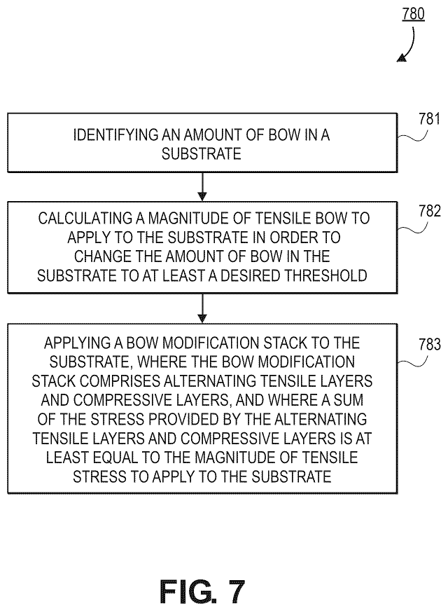

Referring now to FIG. 7, flow diagram that depicts a process 780 for forming a bow mitigation stack on the backside of a substrate is shown, in accordance with an embodiment. In an embodiment, the bow mitigation stack may be similar to any of the bow mitigation stacks described in greater detail herein. In an embodiment, the process 780 may begin with operation 781, which comprises identifying an amount of bow in a substrate. In an embodiment, the amount of bow in the substrate may be measured with any suitable process, such as a capacitive measurements, laser sensing, profilometry, or the like.

In an embodiment, the process 780 may continue with operation 782 (in the FIG. 7, change “STRESS” in 782 block to “BOW”), which comprises calculating a magnitude of tensile bow to apply to the substrate in order to change the amount of bow in the substrate to at least a desired threshold. In an embodiment, the calculation may be implemented by a processor or other computation device that is able to model the response of the substrate to various amounts of induced stress. In some embodiments, the desired threshold may be so that there is substantially no bow in the substrate. Other embodiments may include a threshold amount of bow that enables subsequent chucking of the substrate for further processing.

In an embodiment, the process 780 may continue with operation 783, which comprises applying a bow modification stack to the substrate. In an embodiment, the bow modification stack may comprise alternating tensile layers and compressive layers. A sum of the stress provided by the alternating tensile layers and compressive layers may be at least equal to the magnitude of tensile stress to apply to the substrate to bring the substrate bow to at least the desired threshold. In an embodiment, the alternating tensile layers and compressive layers may be substantially similar to any of the tensile layers and compressive layers described in greater detail herein. For example, the tensile layers may comprise amorphous silicon with (or without dopants), and the compressive layers may comprise silicon oxide or the like. In an embodiment, the bow modification stack may comprise layers that are similar to any of the bow modification stacks described in greater detail herein.

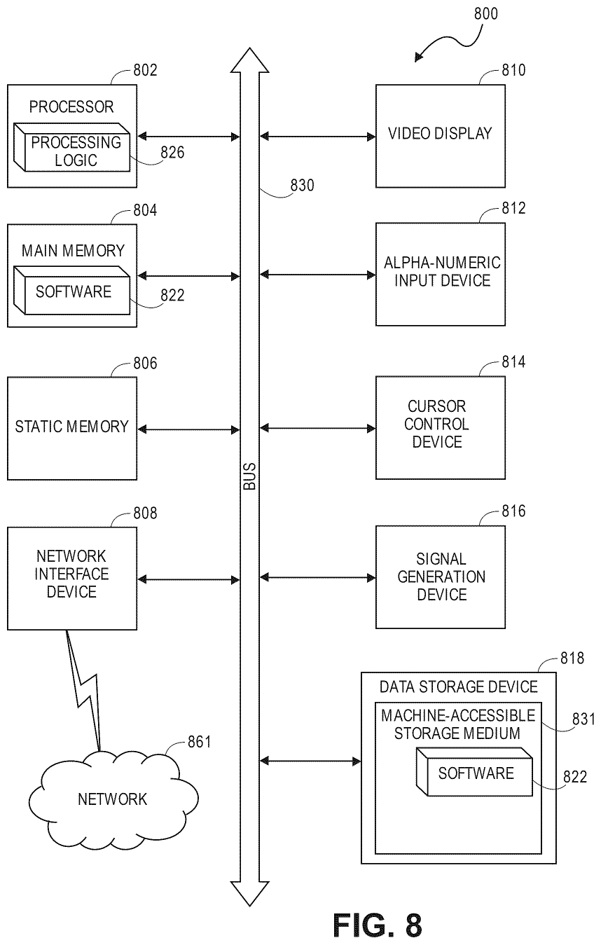

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
depositing a first layer with a first material composition on a surface of a substrate, wherein the substrate has a first bow prior to depositing the first layer on the surface of the substrate, and wherein the first layer comprises a tensile stress with a first magnitude; and
depositing a second layer with a second material composition on the first layer, wherein the second layer comprises a compressive stress with a second magnitude, wherein the second magnitude is smaller than the first magnitude, and wherein the first layer and the second layer produce a second bow for the substrate that is different than the first bow.

2. The method of claim 1, further comprising:
depositing a third layer with a third material composition on the second layer, wherein the third layer comprises a tensile stress with a third magnitude; and
depositing a fourth layer with a fourth material composition on the third layer, wherein the fourth layer comprises a compressive stress with a fourth magnitude that is smaller than the third magnitude.

3. The method of claim 1, wherein the first material composition comprises amorphous silicon.

4. The method of claim 3, wherein the amorphous silicon is doped with nitrogen and/or boron.

5. The method of claim 1, wherein the first material composition comprises a silicon nitride.

6. The method of claim 1, wherein the second material composition comprises a silicon oxide.

7. The method of claim 1, wherein the first layer has a first thickness and the second layer has a second thickness that is less than the first thickness.

8. The method of claim 7, wherein the first thickness is less than 1.0 μm.

9. The method of claim 1, wherein the first layer and the second layer are deposited in a single plasma enhanced chemical vapor deposition (PECVD) chamber.

10. The method of claim 1, wherein the first bow and the second bow have a difference between 500 μm and 1,000 μm.

11. A method, comprising:
depositing a first bow modification stack on a surface of a substrate, wherein the first bow modification stack comprises:
a first layer comprising a first tensile stress; and
a second layer comprising a first compressive stress, wherein the first bow modification stack has a first net tensile stress; and
depositing a second bow modification stack on the first bow modification stack, wherein the second bow modification stack comprises:
a third layer comprising a second tensile stress; and
a fourth layer comprising a second compressive stress, wherein the second bow modification stack has a second net tensile stress.

12. The method of claim 11, wherein the first layer and the third layer comprise an amorphous silicon material.

13. The method of claim 12, wherein the amorphous silicon material comprises nitrogen dopants and/or boron dopants.

14. The method of claim 11, wherein the second layer and the fourth layer comprise a silicon oxide material.

15. The method of claim 11, wherein the fourth layer is thicker than the second layer.

16. The method of claim 11, wherein the first layer and the third layer have different thicknesses.

17. The method of claim 11, further comprising:
depositing one or more additional bow modification stacks over the second bow modification stack, wherein the one or more additional bow modification stacks each comprise:
a tensile stress layer; and
a compressive layer over the tensile stress layer, wherein a net stress of the one or more additional bow modification stacks is a tensile stress.

18. A method, comprising:
calculating a magnitude of tensile stress to apply to a substrate in order to change an amount of bow in the substrate to at least a desired threshold; and
applying a bow modification stack to the substrate, wherein the bow modification stack comprises alternating tensile layers and compressive layers, and wherein a sum of the stress provided by the alternating tensile layers and compressive layers is at least equal to the magnitude of tensile stress to apply to the substrate.

19. The method of claim 18, wherein the tensile layers comprise uniform thicknesses.

20. The method of claim 18, wherein an outermost compressive layer is thicker than any underlying compressive layers.
